(19) United States
(12) Patent Application Publication
(10) Pub. No.: US 2026/0143968 A1
(43) Pub. Date: May 21, 2026

(54) PIEZOELECTRIC ACTUATOR AND LIQUID EJECTION HEAD

(71) Applicant: SEIKO EPSON CORPORATION, Tokyo (JP)

(72) Inventors: Takeru HATO, MATSUMOTO-SHI (JP); Harunobu KOIKE, MATSUMOTO-SHI (JP)

(21) Appl. No.: 19/390,992

(22) Filed: Nov. 17, 2025

(30) Foreign Application Priority Data
Nov. 19, 2024 (JP) 2024-201350

(51) Int. Cl. H10N 30/20; B41J 2/14; H10N 30/87

(52) U.S. Cl. CPC H10N 30/2047; B41J 2/14233; H10N 30/872; H10N 30/875; B41J 2002/14491

(57) ABSTRACT

A piezoelectric actuator includes a piezoelectric element, and a vibrating plate that vibrates through driving of the piezoelectric element. The vibrating plate includes a first layer containing zirconium oxide as a main constituent material. When zirconium oxide contained in the first layer is measured by X-ray diffraction, and when an intensity related to a cubic crystal (111) is defined as a first intensity and an intensity related to a monoclinic crystal (111) is defined as a second intensity, the ratio of the first intensity to the sum of the first intensity and the second intensity is 40% or more.

The present application is based on, and claims priority from JP Application Serial Number 2024-201350, filed Nov. 19, 2024, the disclosure of which is hereby incorporated by reference herein in its entirety.

### BACKGROUND

### 1. Technical Field

The present disclosure relates to a piezoelectric actuator and a liquid ejection head.

### 2. Related Art

JP-A-2005-176433 discloses an actuator device including a vibrating plate, and a piezoelectric element formed on the vibrating plate. In JP-A-2005-176433, the vibrating plate is formed by forming an insulator film made of monoclinic zirconium oxide preferentially oriented in (−111) on an elastic film made of silicon oxide.

In the technique described in JP-A-2005-176433, cracks may occur depending on the crystallinity or orientation of zirconium oxide.

### SUMMARY

To solve the above problem, a piezoelectric actuator according to a preferred aspect of the present disclosure includes a piezoelectric element, and a vibrating plate that vibrates through driving of the piezoelectric element, wherein the vibrating plate includes a first layer containing zirconium oxide as a main constituent material, and when zirconium oxide contained in the first layer is measured by X-ray diffraction, and when an intensity related to a cubic crystal (111) is defined as a first intensity and an intensity related to a monoclinic crystal (111) is defined as a second intensity, a ratio of the first intensity to a sum of the first intensity and the second intensity is 40% or more.

A liquid ejection head according to a preferred aspect of the present disclosure includes the piezoelectric actuator according to the aspect described above.

### BRIEF DESCRIPTION OF THE DRAWINGS

FIG. 1 is a schematic diagram of a configuration example of a liquid ejecting apparatus.

FIG. 2 is an exploded perspective view of a liquid ejection head according to an embodiment.

FIG. 3 is a cross-sectional view taken along line III-III in FIG. 2.

FIG. 4 is a plan view of a portion of the liquid ejection head shown in FIG. 2.

FIG. 5 is a cross-sectional view taken along line V-V in FIG. 4.

FIG. 6 is an explanatory diagram of a first intensity and a second intensity.

FIG. 7 is an explanatory diagram of a method for manufacturing a piezoelectric actuator according to the embodiment.

FIG. 8 is an explanatory diagram of the method for manufacturing a piezoelectric actuator according to the embodiment.

FIG. 9 is a diagram showing the conditions and evaluation results of Examples 1 to 6 and Comparative Example.

FIG. 10 is a diagram showing additive elements of Zr targets used in Examples 1 to 6 and Comparative Example.

FIG. 11 is a diagram showing the results of X-ray analysis of a second layer of Example 1 and Comparative Example.

### DESCRIPTION OF EMBODIMENTS

Hereinafter, preferred embodiments according to the present disclosure will be described with reference to the accompanying drawings. In the drawings, dimensions and scale of each portion are appropriately different from actual ones, and some portions are schematically illustrated for easy understanding. In addition, the scope of the present disclosure is not limited to these forms unless it is stated in the following description that the present disclosure is particularly limited.

For convenience, an X axis, a Y axis, and a Z axis intersecting with each other will be appropriately used in the following description. Hereinafter, one direction along the X axis will be referred to as an X1 direction, and a direction opposite to the X1 direction will be referred to as an X2 direction. Similarly, directions opposite to each other along the Y axis are a Y1 direction and a Y2 direction. Further, directions opposite to each other along the Z axis are a Z1 direction and a Z2 direction. The Z1 direction is an example of “the thickness direction of the first layer.”

Here, typically, the Z axis is a vertical axis, and the Z2 direction corresponds to a downward direction in the vertical direction. The Z axis may not be the vertical axis. The X axis, the Y axis, and the Z axis are typically orthogonal to each other, but are not limited thereto, and need only to intersect each other at an angle within a range of, for example, 80° or more and 100° or less.

### 1. EMBODIMENT

### 1-1. Overall Configuration of Liquid Ejecting Apparatus

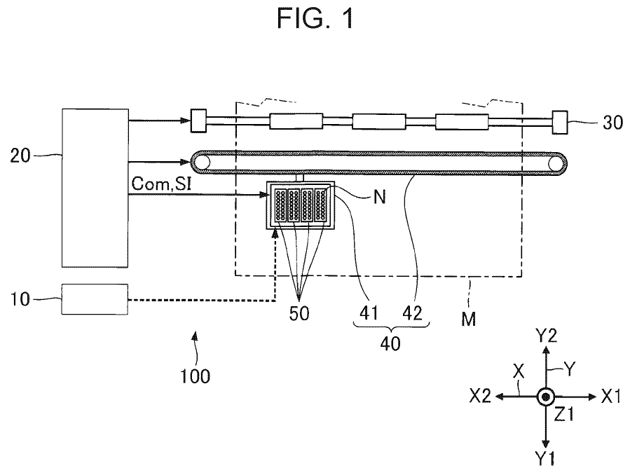

FIG. 1 is a schematic diagram of a configuration example of a liquid ejecting apparatus 100 according to an embodiment. The liquid ejecting apparatus 100 is an ink jet printing apparatus that ejects ink, which is an example of “liquid,” as liquid droplets toward a recording medium M. The recording medium M is, for example, a printing sheet. Note that the recording medium M is not limited to the printing paper, and may be, for example, a printing target made of any material such as resin film or fabric.

As shown in FIG. 1, the liquid ejecting apparatus 100 includes a liquid container 10, a control module 20, a transport mechanism 30, a moving mechanism 40, and a plurality of liquid ejection heads 50.

The liquid container 10 stores ink. Examples of a specific aspect of the liquid container 10 include a cartridge that can be attached to and detached from the liquid ejecting apparatus 100, a bag-shaped ink pack made of a flexible film, and an ink tank that can be refilled with ink. Note that any kind of ink is stored in the liquid container 10.

The control module 20 controls the operation of each element of the liquid ejecting apparatus 100. The control module 20 includes, for example, a processing circuit such as a central processing unit (CPU) or a field programmable gate array (FPGA) and a storage circuit such as a semiconductor memory. Here, the control module 20 outputs a drive signal Com for driving the liquid ejection heads 50 and a control signal SI for controlling the drive of the liquid ejection heads 50. The control module 20 controls an ejection operation from the liquid ejection heads 50 with the drive signal Com and the control signal SI.

The transport mechanism 30 transports the recording medium M along the Y axis under the control of the control module 20.

The moving mechanism 40 reciprocates the liquid ejection heads 50 along the X axis under the control of the control module 20. The moving mechanism 40 includes a substantially box-shaped transport body 41 called a carriage that accommodates the liquid ejection heads 50, and an endless transport belt 42 to which the transport body 41 is fixed. In addition to the liquid ejection heads 50, the liquid container 10 described above may be mounted on the transport body 41.

Each of the liquid ejection heads 50 ejects the ink supplied from the liquid container 10 onto the recording medium M from each of a plurality of nozzles N under the control of the control module 20. This ejection is performed in parallel with the transport of the recording medium M by the transport mechanism 30 and the reciprocating movement of the liquid ejection heads 50 by the moving mechanism 40, and thus an image with the ink is formed on the surface of the recording medium M.

In the example shown in FIG. 1, the number of the liquid ejection heads 50 is four. Note that the number of the liquid ejection heads 50 is not limited to the example shown in FIG. 1, and any number, which may be single or a plural number of three or less or five or more. Further, the arrangement of the liquid ejection heads 50 is not limited to the example shown in FIG. 1, and may be any arrangement.

### 1-2. Liquid Ejection Head

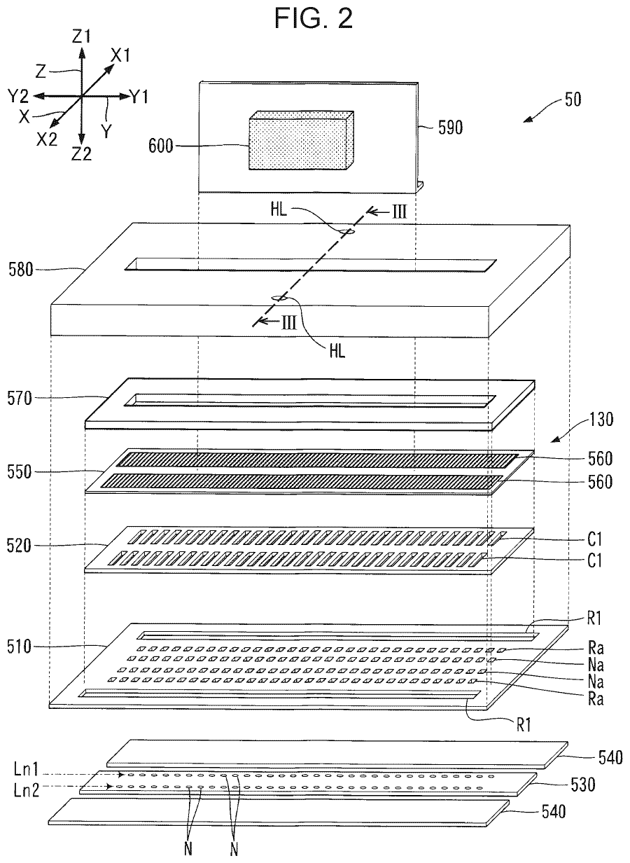

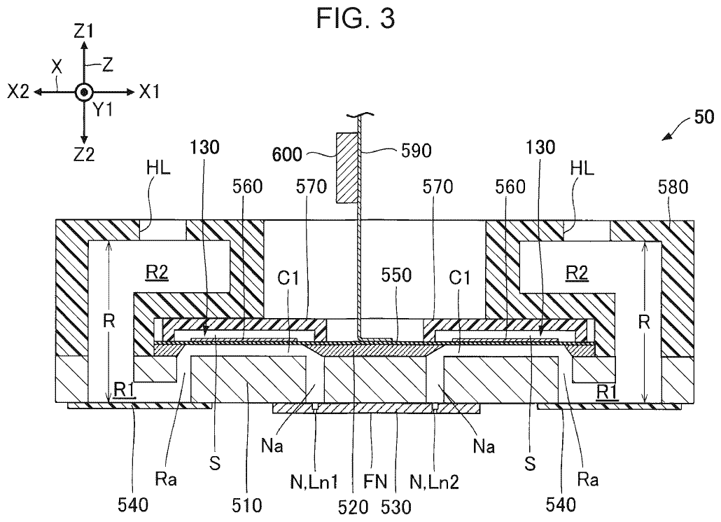

FIG. 2 is an exploded perspective view of the liquid ejection head 50 according to the embodiment. FIG. 3 is a cross-sectional view taken along line III-III in FIG. 2. Hereinafter, an example of the configuration of the liquid ejection head 50 will be described.

As shown in FIG. 2 and FIG. 3, the liquid ejection head 50 includes a plurality of nozzles N arranged in a direction along the Y axis.

The nozzles N included in the liquid ejection head 50 are divided into a first nozzle row Ln1 and a second nozzle row Ln2 that are arranged spaced apart from each other in a direction along the X axis. Each of the first nozzle row Ln1 and the second nozzle row Ln2 is a set of a plurality of nozzles N linearly arranged in the direction along the Y axis.

The liquid ejection head 50 is configured to be substantially symmetrical to each other in the direction along the X axis. However, the positions of the nozzles N of the first nozzle row Ln1 and the nozzles N of the second nozzle row Ln2 in the direction along the Y axis may match each other or may be different from each other. FIG. 2 and FIG. 3 illustrate a configuration in which the positions of the nozzles N of the first nozzle row Ln1 and the nozzles N of the second nozzle row Ln2 in the direction along the Y-axis match each other.

As shown in FIG. 2 and FIG. 3, the liquid ejection head 50 includes a communication substrate 510, a pressure chamber substrate 520, a nozzle plate 530, a vibration absorber 540, a vibrating plate 550, a plurality of piezoelectric elements 560, a protective substrate 570, a case 580, and a wiring substrate 590. Here, the piezoelectric elements 560 and the vibrating plate 550 constitute a piezoelectric actuator 130. Thus, the piezoelectric actuator 130 includes the piezoelectric elements 560 and the vibrating plate 550.

Thus, the liquid ejection head 50 includes the piezoelectric actuator 130. Accordingly, since the occurrence of cracks in the piezoelectric actuator 130 is reduced as will be described below, it is possible to provide the liquid ejection head 50 having excellent reliability.

The communication substrate 510 and the pressure chamber substrate 520 are stacked in this order in the Z1 direction, and form flow paths for supplying ink to the nozzles N. The vibrating plate 550, the piezoelectric elements 560, the protective substrate 570, the case 580, the wiring substrate 590, and a drive circuit 600 are installed in a region positioned more in the Z1 direction than a stacked body formed of the communication substrate 510 and the pressure chamber substrate 520. On the other hand, the nozzle plate 530 and the vibration absorber 540 are installed in a region positioned more in the Z2 direction than the stacked body. The elements of the liquid ejection head 50 are each schematically a plate-shaped member elongated in the Y direction, and are bonded to each other with, for example, an adhesive. Hereinafter, each element of the liquid ejection head 50 will be described in order.

The nozzle plate 530 is a plate-shaped member in which the nozzles N of each of the first nozzle row Ln1 and the second nozzle row Ln2 are provided. Each of the nozzles N is a through hole for the ink to pass through. Here, a surface of the nozzle plate 530 facing the Z2 direction is a nozzle surface FN. The nozzle plate 530 is manufactured, for example, through processing of a silicon single crystal substrate by a semiconductor manufacturing technique using a processing technique such as dry etching or wet etching. However, other known methods and materials may be appropriately used to manufacture the nozzle plate 530. In addition, the cross-sectional shape of the nozzle N is typically a circular shape, but the shape is not limited thereto, and may be, for example, a non-circular shape such as a polygonal or an elliptical shape.

The communication substrate 510 is provided with a flow path R1, a plurality of supply flow paths Ra, and a plurality of communication flow paths Na for each of the first nozzle row Ln1 and the second nozzle row Ln2. The flow path R1 is a flow path provided in common to the nozzles N, is a flow path that communicates with the nozzles N and that is upstream from the nozzles N, and is formed of an elongated hole extending in the direction along the Y axis in a plan view as viewed in a direction along the Z axis. Each of the supply flow paths Ra and the communication flow paths Na is a flow path including a through hole formed for each nozzle N. Each supply flow path Ra communicates with the flow path R1.

Similarly to the above-described nozzle plate 530, the communication substrate 510 is manufactured, for example, through processing of a silicon single crystal substrate by a semiconductor manufacturing technique. However, other known methods and materials may be appropriately used to manufacture the communication substrate 510.

The pressure chamber substrate 520 is a plate-shaped member in which a plurality of pressure chambers C1 that are called cavities are provided for each of the first nozzle row Ln1 and the second nozzle row Ln2. The pressure chambers C1 are arranged in the direction along the Y axis. Each pressure chamber C1 is an elongated space formed for each nozzle N and extending in the direction along the X axis in a plan view. As described above, the pressure chamber substrate 520 includes the pressure chambers C1 arranged in the Y1 direction or the Y2 direction.

Similarly to the above-described nozzle plate 530, the pressure chamber substrate 520 is manufactured, for example, through processing of a silicon single crystal substrate by a semiconductor manufacturing technique. However, other known methods and materials may be appropriately used to manufacture the pressure chamber substrate 520.

The pressure chambers C1 are positioned between the communication substrate 510 and the vibrating plate 550. For each of the first nozzle row Ln1 and the second nozzle row Ln2, the pressure chambers C1 are arranged in the direction along the Y axis. The pressure chambers C1 communicate with each of the communication flow paths Na and the supply flow paths Ra. Therefore, the pressure chambers C1 communicate with the nozzles N via the communication flow paths Na, and communicate with the flow path R1 via the supply flow paths Ra.

The vibrating plate 550 is disposed on the pressure chamber substrate 520, more specifically, on a surface of the pressure chamber substrate 520 facing the Z1 direction. The vibrating plate 550 is a plate-shaped member capable of elastically vibrating, and vibrates through driving of the piezoelectric elements 560. Details of the vibrating plate 550 will be described below based on FIG. 5.

On a surface of the vibrating plate 550 facing the Z1 direction, the piezoelectric elements 560 corresponding to the nozzles N are arranged for each of the first nozzle row Ln1 and the second nozzle row Ln2. Each piezoelectric element 560 is a passive element that is deformed by being supplied with a potential corresponding to the drive signal Com, and generates a pressure fluctuation in the ink inside the pressure chamber C1. Each piezoelectric element 560 has an elongated shape extending in the direction along the X axis in a plan view. The piezoelectric elements 560 are arranged in the direction along the Y axis so as to correspond to the pressure chambers C1. The piezoelectric elements 560 overlap the pressure chambers C1 in a plan view. The above piezoelectric elements 560 apply pressures to the pressure chambers C1 communicating with the nozzles N that eject ink. Details of the piezoelectric element 560 will be described below based on FIG. 5.

The protective substrate 570 is a plate-shaped member installed on the surface of the vibrating plate 550 facing the Z1 direction, protects the piezoelectric elements 560, and reinforces the mechanical strength of the vibrating plate 550. Here, the piezoelectric elements 560 are accommodated in a space S between the protective substrate 570 and the vibrating plate 550. The protective substrate 570 is made of, for example, a resin material.

The case 580 is a case for storing ink to be supplied to the pressure chambers C1. The case 580 is made of, for example, a resin material. The case 580 is provided with a flow path R2 for each of the first nozzle row Ln1 and the second nozzle row Ln2. The flow path R2 is a space connected to the above-described flow path R1, and is formed of an elongated hole extending in the direction along the Y axis in a plan view as viewed in the direction along the Z axis. The flow path R2 communicates with the nozzles N, and functions as a reservoir R that stores the ink to be supplied to the pressure chambers C1 together with the flow path R1. The case 580 is provided with an introduction port HL for supplying ink to each reservoir R. The ink in each reservoir R is supplied to the pressure chamber C1 via each supply flow path Ra. Note that the mode including the position and the number of the introduction port HL with respect to each reservoir R is not limited to the example in FIG. 2 and FIG. 3, and may be any mode.

The vibration absorber 540 is also referred to as a compliance substrate, is a flexible resin film constituting a wall surface of the reservoir R, and absorbs pressure fluctuations of the ink in the reservoir R. Note that the vibration absorber 540 may be a flexible thin plate made of metal. A surface of the vibration absorber 540 facing the Z1 direction is bonded to the communication substrate 510 with an adhesive or the like.

The wiring substrate 590 is mounted on the surface of the vibrating plate 550 facing the Z1 direction, and is a mounted component for electrically connecting the control module 20 and the liquid ejection head 50 to each other. The wiring substrate 590 is, for example, a flexible wiring substrate such as a chip on film (COF), a flexible printed circuit (FPC), or a flexible flat cable (FFC). The drive circuit 600 is mounted on the wiring substrate 590 of the present embodiment. The drive circuit 600 switches whether to supply a pulse included in the drive signal Com output from the control module 20 for each of the piezoelectric elements 560 included in the liquid ejection head 50 under the control of the control module 20. As described above, the wiring substrate 590 supplies the drive signal Com that drives the piezoelectric elements 560. Note that the wiring substrate 590 may be a rigid substrate. In this case, the drive circuit 600 is mounted on the rigid substrate or on a flexible substrate connected to the rigid substrate.

### 1-3. Piezoelectric Actuator

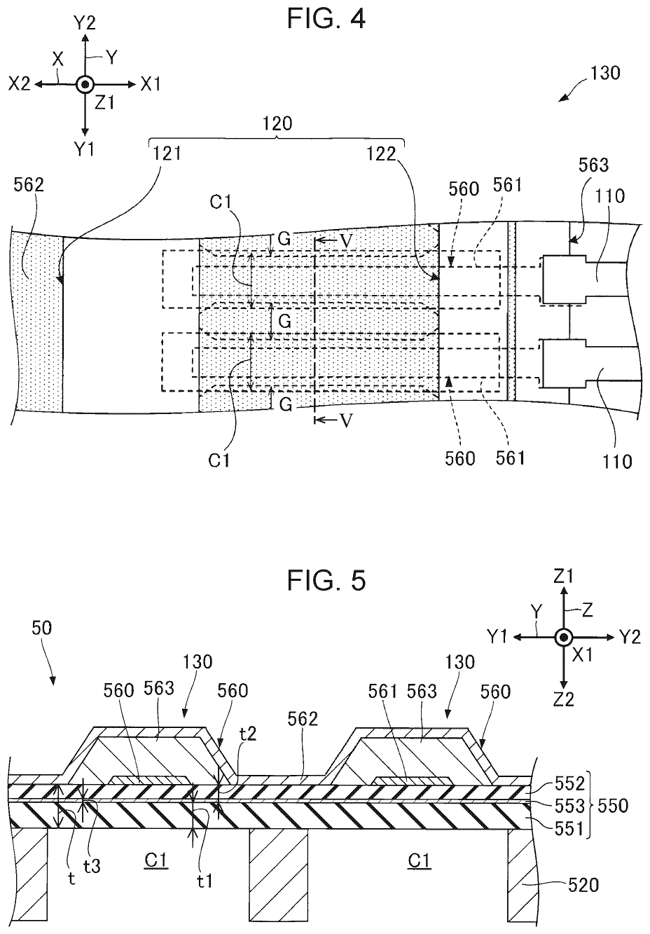

FIG. 4 is a plan view of a portion of the liquid ejection head 50 shown in FIG. 2. FIG. 5 is a cross-sectional view taken along line V-V in FIG. 4. Note that in FIG. 4, for convenience of visibility, a portion of a second electrode 562, which will be described below, that is not covered with a second wire 120, which will be described later, is indicated by dots.

First, the configurations of the vibrating plate 550 and the piezoelectric element 560 will be described based on FIG. 4 and FIG. 5.

The piezoelectric elements 560 are disposed on the surface of the vibrating plate 550 facing the Z1 direction. As shown in FIG. 5, each piezoelectric element 560 includes a first electrode 561, the second electrode 562, and a piezoelectric layer 563. These are stacked in the Z1 direction in the order of the first electrode 561, the piezoelectric layer 563, and the second electrode 562. Note that a seed layer for controlling the orientation of the piezoelectric layer 563 is provided between the first electrode 561 and the piezoelectric layer 563 as necessary, although not shown.

In the piezoelectric element 560, when a voltage is applied between the first electrode 561 and the second electrode 562, the piezoelectric layer 563 is deformed by the inverse piezoelectric effect. When the vibrating plate 550 vibrates in conjunction with this deformation, ink is ejected from the nozzle N due to fluctuations in the pressure inside the pressure chamber C1.

As shown in FIG. 4, a first wire 110 is electrically connected to the first electrode 561, and the drive signal Com is supplied via the first wire 110. The first wire 110 is a lead wire individually provided for each piezoelectric element 560, and is electrically connected to the first electrode 561 of the corresponding piezoelectric element 560. On the other hand, the second wire 120 is electrically connected to the second electrode 562, and a constant potential is supplied via the second wire 120. The second wire 120 is a common wire provided in common to the piezoelectric elements 560, and is electrically connected to the second electrode 562.

In the example shown in FIG. 4, the first wire 110 is connected to the first electrode 561, and is drawn out from the first electrode 561 toward the wiring substrate 590 for each piezoelectric element 560. On the other hand, the second wire 120 is drawn out from the second electrode 562 in a direction toward the wiring substrate 590 to the vibrating plate 550 at both ends of the second electrodes 562 in the Y1 direction and the Y2 direction. Here, the second wire 120 includes band-shaped conductive layers 121 and 122 extending in the Y1 direction. The conductive layer 121 and the conductive layer 122 are arranged at a predetermined interval in the X1 direction. The thus configured second wire 120 also functions as a weight for reducing the vibration of the vibrating plate 550.

The constituent material of each of the first wire 110 and the second wire 120 is not particularly limited, and examples thereof include metals such as gold (Au), copper (Cu), titanium (Ti), tungsten (W), nickel (Ni), chromium (Cr), platinum (Pt), and aluminum (Al). Among them, gold (Au) is suitably used as the constituent material of the first wire 110 and the second wire 120. Here, for each of the first wire 110 and the second wire 120, for example, a structure in which a layer made of gold is stacked as a surface layer on a layer made of nickel-chromium or the like is suitably used.

The first electrode 561 is an individual electrode that is disposed on the vibrating plate 550 and is disposed to be separated from each other for each piezoelectric element 560. The drive signal Com is supplied to the first electrode 561. The second electrode 562 is a band-shaped common electrode that is disposed on the piezoelectric layer 563 and extends in the direction along the Y axis so as to be continuous over the piezoelectric elements 560. For example, a constant potential is supplied to the second electrode 562.

Examples of the material constituting each of the first electrode 561 and the second electrode 562 include metal materials such as platinum (Pt), aluminum (Al), iridium (Ir), nickel (Ni), gold (Au), and copper (Cu), and among these, one type can be used alone, or two or more types can be used in combination in an aspect of alloy or stacking.

The piezoelectric layer 563 is disposed between the first electrode 561 and the second electrode 562, and is made of a piezoelectric material. As the piezoelectric material, a composite oxide having a perovskite structure represented by a general compositional formula ABO₃ is suitably used. Examples of the composite oxide include lead zirconate titanate (Pb(Zr,Ti)O₃) and lead magnesium niobate-lead titanate solid solution (Pb(Mg,Nb)O₃—PbTiO₃). The composite oxide is not limited to the above-described lead-containing compounds, and may be lead-free compounds including, for example, potassium sodium niobate ((K,Na)NbO₃, abbreviated as “KNN”), bismuth ferrate ((BiFeO₃), abbreviated as “BFO”), potassium sodium lithium niobate ((K,Na,Li)(NbO₃)), potassium sodium lithium niobate tantalate ((K,Na,Li)(Nb,Ta)O₃)), and bismuth manganate (BiMnO₃, abbreviated as “BM”).

In the example shown in FIG. 4, the piezoelectric layer 563 has a band shape extending in the direction along the Y axis so as to be continuous over the piezoelectric elements 560. Here, in the piezoelectric layer 563, a notch G penetrating through the piezoelectric layer 563 is provided to extend in the direction along the X axis in a region corresponding to the gap between the pressure chambers C1 adjacent to each other in a plan view. Note that the piezoelectric layer 563 may be individually provided for each piezoelectric element 560. Further, the notch G may be a bottomed groove.

The vibrating plate 550 includes a third layer 551, a first layer 552, and a second layer 553. These layers are stacked in the Z1 direction in the order of the third layer 551, the second layer 553, and the first layer 552. That is, the first layer 552 is disposed at a position in the Z1 direction, and the third layer 551 is disposed at a position in the Z2 direction with respect to the second layer 553. Thus, the second layer 553 is disposed between the third layer 551 and the first layer 552. Note that the interface between the first layer 552 and the second layer 553 is clearly shown in the figure, but the interface may not be clear. For example, each layer may be embedded in, dispersed in, or integrated with another layer.

The third layer 551 is an elastic film containing silicon oxide (SiO₂) as a main constituent material, and is formed by, for example, thermally oxidizing one surface of a silicon single crystal substrate. Note that the third layer 551 may be made of only silicon oxide, or may be made of a material obtained by adding an appropriate element to silicon oxide. Here, the main constituent material refers to a material contained in an amount of 50% or more of the materials constituting the layer.

A thickness t1 of the third layers 551 is determined in accordance with a thickness t, the width, and the like of the vibrating plate 550, and is not particularly limited. However, the thickness is preferably in a range of 100 nm or more and 3,500 nm or less, and more preferably in a range of 500 nm or more and 2,500 nm or less.

The first layer 552 is an insulating film containing zirconium oxide (ZrO₂) as a main constituent material, and is formed by, for example, forming a layer of zirconium by sputtering and thermally oxidizing the layer. Note that the first layer 552 may be made of only zirconium oxide, or may be made of a material obtained by adding an appropriate element to zirconium oxide.

A thickness t2 of the first layer 552 is determined in accordance with the thickness t, the width, and the like of the vibrating plate 550, and is not particularly limited. However, the thickness t2 of the first layer 552 is preferably smaller than the thickness t1 of the third layer 551, and is, for example, in a range of 10 nm or more and 2,000 nm or less. Note that the thickness t2 of the first layer 552 may be equal to or larger than the thickness t1 of the third layers 551.

The second layer 553 is a layer containing an additive different from the main constituent material constituting the first layer 552. The second layer 553 is a layer derived from a layer formed for diffusing the additive into the first layer 552, and is a layer in which the additive and the main constituent material constituting the first layer 552 are mixed. Therefore, the content of the additive in the second layer 553 with respect to the main constituent element of the first layer 552 is higher than the content in the first layer 552.

A thickness t3 of the second layer 553 depends on the diffusivity of the additive, and is in a range of 1 nm or more and 15 nm or less. Note that the interface between the second layer 553 and the first layer 552 is not clear in some cases because the additive diffuses into the first layer 552.

The additive is a material containing one or two or more elements selected from carbon (C), aluminum (Al), titanium (Ti), chromium (Cr), iron (Fe), hafnium (Hf), yttrium (Y), cerium (Ce), silicon (Si), tantalum (Ta), and iridium (Ir) in any state of a simple substance, an oxide, and a nitride. Preferably, the additive contains one or two or more elements selected from carbon, titanium, hafnium, and cerium in any state of a simple substance, an oxide, and a nitride. For example, when the additive contains titanium, hafnium, or cerium, since these elements are elements having the same valence as zirconium contained in the first layer 552, a leakage current can be reduced.

Note that the first layer 552 contains the additive contained in the second layer 553. The additive contained in the first layer 552 is contained, for example, at a ratio of 0.01% or more and 1% or less with respect to zirconium oxide (ZrO₂) as the main constituent material.

Note that the vibrating plate 550 is not limited to the above-described configuration in which the third layer 551 and the first layer 552 are stacked, and may include, for example, a single layer formed of the first layer 552 or three or more layers.

For example, an adhesion layer that enhances adhesion to the first layer 552 or the second layer 553 may be provided on a surface of the third layer 551 facing the Z1 direction. The adhesion layer is made of a material different from those of the third layer 551 and the first layer 552. For example, the adhesion layer is made of titanium oxide.

Further, the arrangement of the second layer 553 is not limited to the above-described arrangement, and may be the following arrangement. For example, the second layer 553 may be formed on a surface of the first layer 552 facing the Z1 direction. In this case, the additive diffuses inward from the surface of the first layer 552 facing the Z1 direction. Further, the second layer 553 may be formed on both a surface of the first layer 552 facing the Z2 direction and on the surface of the first layer 552 facing the Z1 direction.

In addition, without forming a region having a high concentration of the additive with respect to the main constituent element as in the second layer 553, the concentration of the additive may be uniform in the first layer 552. In this case, when the first layer 552 is formed, a target is doped with the additive or ions are implanted into the first layer 552, so that the first layer 552 is caused to contain the additive.

In addition, the third layer 551 is not limited to a configuration formed of silicon oxide (SiO₂) as the main constituent element. For example, the third layer 551 may be formed of a single layer or a plurality of layers made of a material containing one or two or more elements selected from titanium (Ti), silicon (Si), aluminum (Al), tantalum (Ta), chromium (Cr), iridium (Ir), hafnium (Hf), zirconium (Zr), and carbon (C) in any state of a simple substance, an oxide, or a nitride. For example, the third layer 551 may have a configuration in which a plurality of layers of silicon oxide (SiO₂) and silicon nitride (SiN) are stacked. Further, the third layer 551 may have a structure in which a plurality of layers of silicon oxide (SiO₂) and titanium oxide (TiO₂) are stacked.

In addition, the magnitude relation between the thicknesses of the third layer 551 and the first layer 552 is not limited to the example shown in the figure, and may be any relation.

In the vibrating plate 550 having the above-described schematic configuration, the inventor has conducted diligent research to find that the occurrence of cracks in the first layer 552 is caused by the ratio between the cubic crystal and the monoclinic crystal of zirconium oxide. It is considered that one of the reasons why the occurrence of cracks can be reduced is that, in a region where crystal grains of zirconium oxide grow so as to be inclined with respect to a substrate, a force that pushes out a film in a planar direction is generated along with crystal growth, compared to a case where crystal grains grow perpendicularly to the substrate. As a result, it is considered that the tensile stress of the first layer 552 is reduced due to an increase in the ratio of the cubic crystal, and thus cracks are less likely to occur. In the related art, the relation between the ratio between the cubic crystal and the monoclinic crystal of zirconium oxide and the reduction in the tensile stress has not been known.

The film stress of a thin film on a substrate is expressed by Stoney's equation below:

$$σ = \frac{{Et}_{s}^{2}}{( 1 - v ) 6 {t}_{f}} ( \frac{1}{{R}_{fs}} - \frac{1}{{R}_{s}} )$$

Here, σ is the film stress of the thin film, E is Young's modulus, tₛ is the thickness of the substrate, t_{f} is the thickness of the thin film, ν is Poisson's ratio, R_{fs} is the curvature radius of the substrate after film formation (the staked body of the thin film and the substrate), and Rₛ is the curvature radius of the substrate before film formation.

As shown by this equation, the film stress is in a proportional relation with Young's modulus. Therefore, as Young's modulus decreases, the film stress decreases.

On the other hand, it is known that the Young's modulus (212 GPa) of cubic zirconium oxide is smaller than the Young's modulus (249 GPa or 241 GPa) of monoclinic zirconium oxide.

As a result of the above-described studies, when zirconium oxide contained in the first layer 552 is measured by X-ray diffraction, when an intensity related to a cubic crystal (111) is a first intensity P1 and an intensity related to a monoclinic crystal (111) is a second intensity P2, the ratio P1/(P1+P2) of the first intensity P1 to the sum (P1+P2) of the first intensity P1 and the second intensity P2 is 40% or more. Thus, the ratio of the cubic crystal (111) can be increased with respect to the monoclinic crystal (111) in zirconium oxide contained in the first layer 552. As a result, the occurrence of cracks can be reduced.

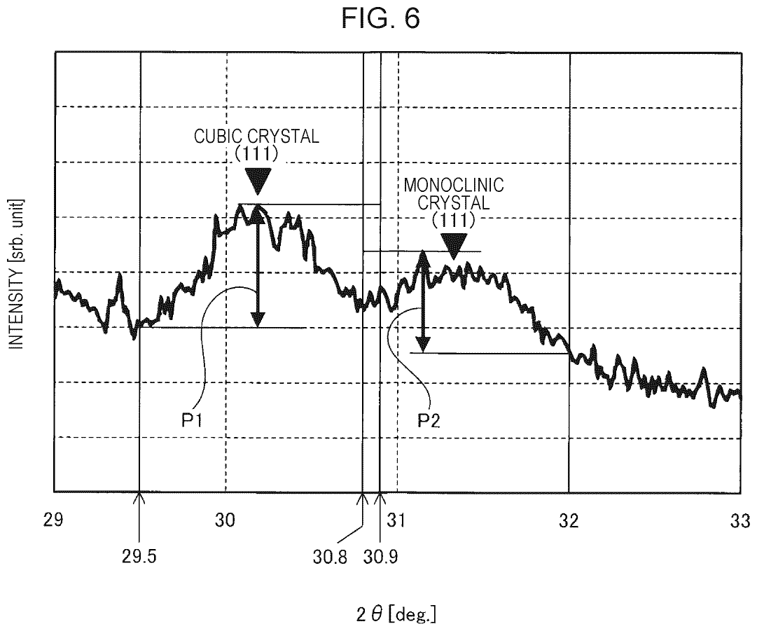

FIG. 6 is an explanatory diagram of the first intensity P1 and the second intensity P2. FIG. 6 shows a result of X-ray analysis of the first layer 552 having a configuration corresponding to Example 5 described below.

Here, the first intensity P1 is the difference between the maximum value and the minimum value of the spectrum in a range where the peak of the cubic crystal (111) exists. The second intensity P2 is the difference between the maximum value and the minimum value of the spectrum in a range where the peak of the monoclinic crystal (111) exists.

The ratio P1/(P2+P1) of the first intensity P1 to the sum (P1+P2) of the first intensity P1 and the second intensity P2 is preferably 50% or more, and more preferably 57% or more. When the ratio P1/(P1+P2) is 50% or more, the displacement of the vibrating plate 550 can be increased while reducing the occurrence of cracks, compared to an aspect in which the ratio P1/(P1+P2) is less than 50%. When the ratio P1/(P1+P2) is 57% or more, the film stress of the first layer 552 can be made 100 MPa or less. As a result, the occurrence of cracks in the vibrating plate 550 can be suitably reduced. Note that when the ratio P1/(P1+P2) is 57% or more, the first intensity P1 is larger than the second intensity P2.

The tensile stress of the first layer 552 is preferably 100 MPa or less. As a result, the occurrence of cracks in the vibrating plate 550 can be reduced. On the other hand, when the tensile stress of the first layer 552 is excessively large, there is a concern that cracks may occur in the vibrating plate 550.

The compressive stress refers to an internal stress, when one of two target layers receives a compressive force due to another layer, generated in the other layer. The internal stress has a repulsive force against a compressive force that the other layer receives from the one layer. On the other hand, the tensile stress refers to an internal stress, when one of two target layers receives a tensile force due to another layer, generated in the other layer. The internal stress has a repulsive force against a tensile force that the other layer receives from the one layer.

The first layer 552 preferably contains, in addition to zirconium oxide, at least one element out of carbon, aluminum, titanium, chromium, iron, hafnium, yttrium, and cerium. As a result, the first intensity P1 can be suitably made larger than the second intensity P2. That is, the ratio of the cubic crystal (111) can be increased.

The at least one element is contained in the first layer 552 as an additive element. Such a first layer 552 is formed by diffusing the additive contained in the second layer 553 into the first layer 552. In addition, such a first layer 552 may be formed by sputtering or the like using a target containing the at least one element, or may be formed by introducing the at least one element into a zirconium oxide layer formed by any method by ion implantation or the like.

In particular, the first layer 552 preferably contains an element having the same valence as zirconium as the additive element. As a result, the insulation properties of the first layer 552 can be enhanced, and a leakage current to the vibrating plate 550 can be reduced.

Examples of the element having the same valence as Zr (valence: 4+) include titanium, hafnium, and cerium.

Further, the first layer 552 preferably contains carbon. As a result, the film stress of the first layer 552 can be reduced while increasing the ratio of the cubic crystal (111).

When the second layer 553 containing the additive element added to the first layer 552 is formed, the additive element is contained in the first layer 552. By supplying the additive from the second layer 553 to the first layer 552, the first intensity P1 can be suitably made larger than the second intensity P2. As a result, the ratio of the cubic crystal (111) can be increased.

When the second layer 553 contains titanium, the thickness of the second layer 553 is 1 nm or more and 15 nm or less, and preferably 1 nm or more and 10 nm or less. When the second layer 553 contains titanium, which easily thermally diffuses, titanium can be suitably diffused as the additive element into the first layer 552. Note that when the thickness of the second layer 553 is larger than 15 nm, the amount of titanium that diffuses into the first layer 552 increases, portions where the densities of the second layer 553 and the first layer 552 are sparse are generated, and as a result, there is a concern that the vibrating plate 550 may become fragile. By making the thickness of the second layer 553 15 nm or less, an increase in the fragility of the vibrating plate 550 can be reduced.

Note that the titanium that has diffused into the first layer 552 substitutes, for example, for the zirconium site of zirconium oxide.

When the second layer 553 containing the additive element added to the first layer 552 is formed on the first layer 552, the additive element is contained in the first layer 552. By supplying the additive from the second layer 553 to the first layer 552, the first intensity P1 can be suitably made larger than the second intensity P2. As a result, the ratio of the cubic crystal (111) can be increased.

### 1-4. Method for Manufacturing Piezoelectric Actuator

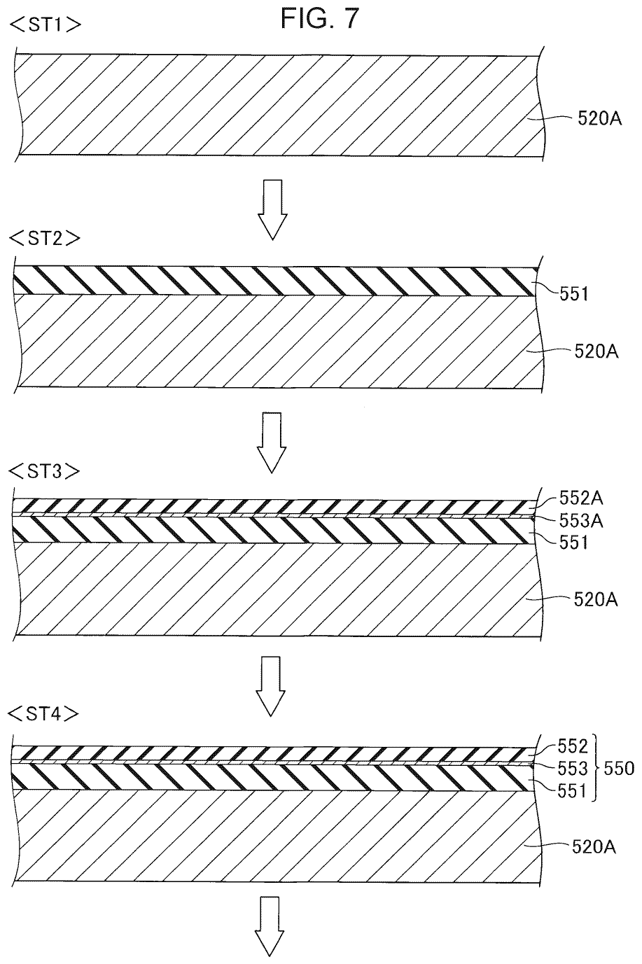

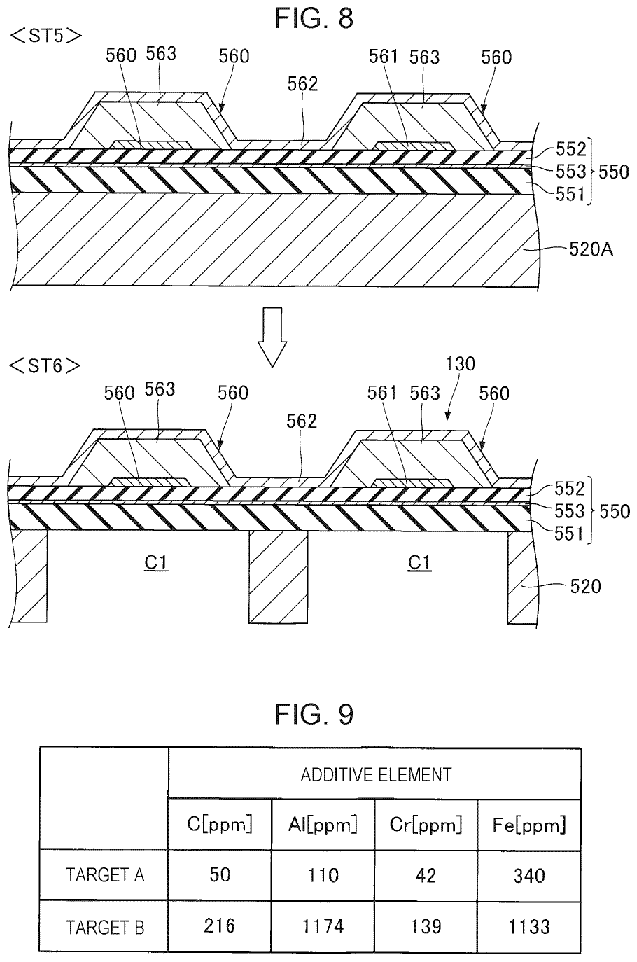

FIG. 7 and FIG. 8 are explanatory diagrams of a method for manufacturing the piezoelectric actuator 130 according to the embodiment. As shown in FIG. 7 and FIG. 8, the method for manufacturing the piezoelectric actuator 130 includes Step ST1 to Step ST6 in this order. Hereinafter, each step will be described in order.

In Step ST1, a substrate 520A is prepared. The substrate 520A is a substrate that becomes the pressure chamber substrate 520 through processing, and is, for example, a silicon single crystal substrate.

In Step ST2, after Step ST1, the third layer 551 is formed on one surface of the substrate 520A. The third layer 551 is formed by, for example, thermally oxidizing the one surface of the substrate 520A.

In Step ST3, after Step ST2, layers 553A and 552A are formed in this order on the third layer 551. The layer 553A is a layer for forming the second layer 553, and is formed by, for example, forming a titanium film by sputtering. The layer 552A is a layer for forming the first layer 552 and is formed by, for example, forming a zirconium film by sputtering.

In Step ST4, after Step ST3, the layers 553A and 552A are simultaneously thermally oxidized to form the second layer 553 and the first layer 552. As a result, the vibrating plate 550 is formed.

In Step ST4, at least a portion of the element such as titanium contained in the layer 553A diffuses into the layer 552A. As a result, the ratio of the cubic crystal (111) of zirconium oxide in the first layer 552 can be increased.

The heating temperature in Step ST4 is, for example, preferably 500° C. or higher and 1,000° C. or lower, and preferably 500° C. or higher and 700° C. or lower. As a result, the ratio of the cubic crystal (111) of zirconium oxide in the first layer 552 can be increased. In Step ST5, after Step ST4, the piezoelectric elements 560 are formed on the first layer 552. Specifically, in Step ST5, the first electrode 561, the piezoelectric layer 563, and the second electrode 562 are formed on the vibrating plate 550 in this order. Here, the formation of each of the first electrode 561 and the second electrode 562 is performed using, for example, a known film forming technique such as sputtering and a known processing technique using photolithography, etching, and the like. The formation of the piezoelectric layer 563 is performed by, for example, forming a precursor layer of a piezoelectric body by a solution process, and then firing the precursor layer to crystallize the precursor layer. In addition, a polarization treatment is performed on the piezoelectric layer 563 by applying a voltage between the first electrode 561 and the second electrode 562.

In Step ST6, after Step ST5, a plurality of pressure chambers C1 are formed in the substrate 520A. As a result, the pressure chamber substrate 520 is formed. Thus, the piezoelectric actuator 130 is obtained. Further, after Step ST6, the liquid ejection head 50 is obtained through a known appropriate step.

Note that when the adhesion layer is provided on the upper surface of the third layer 551, forming the adhesion layer is provided between Step ST2 and Step ST3. In this step, for example, a layer for forming the adhesion layer is formed by forming a titanium film by sputtering, and the layer is heated to oxidize titanium, thus forming the adhesion layer formed of titanium oxide. Here, as described above, the second layer 553 and the adhesion layer have different steps of forming them.

### 2. EXAMPLES

Hereinafter, specific examples will be described.

### 2-1. Manufacture of Piezoelectric Actuator

### 2-1-1. Example 1

First, one surface of a silicon single crystal substrate having a plane orientation (110) was thermally oxidized to form a first layer of 1,500 nm thick made of silicon oxide.

Next, on the first layer, a titanium film of 10 nm thick and a zirconium film of 400 nm thick were formed in this order by sputtering, and then these films were thermally oxidized and fired at an annealing temperature of 600° C. to form a second layer and a third layer. Here, for the formation of the film made of zirconium, as shown in FIG. 9, a target B containing an additive element was used as a Zr target.

Then, a stacked body including a titanium layer, a platinum layer, and an iridium layer was formed on the second layer by sputtering, and then the stacked body was processed using photolithography and dry etching to form a first electrode of a piezoelectric element.

Next, a piezoelectric layer made of lead zirconate titanate and including a plurality of layers was formed using a solution process.

Next, a second electrode including an iridium layer and a titanium layer was formed on the piezoelectric layer by sputtering.

Thereafter, the other surface of the silicon single crystal substrate was subjected to anisotropic etching using a potassium hydroxide aqueous solution (KOH) or the like as an etchant, thereby forming a pressure chamber. Thus, a piezoelectric actuator was manufactured.

### 2-1-2. Example 2

A piezoelectric actuator was manufactured in the same manner as in Example 1 except that the formation of the film made of titanium was omitted, that is, the formation of the third layer was omitted.

### 2-1-3. Example 3

A piezoelectric actuator was manufactured in the same manner as in Example 1 except that the thickness of the titanium film was 2 nm.

### 2-1-4. Example 4

A piezoelectric actuator was manufactured in the same manner as in Example 1 except that the annealing temperature was 900° C.

### 2-1-5. Example 5

A piezoelectric actuator was manufactured in the same manner as in Example 2 except that the annealing temperature was 900° C.

### 2-1-6. Example 6

A piezoelectric actuator was manufactured in the same manner as in Example 4 except that a target A shown in FIG. 9 was used as the Zr target. That is, a piezoelectric actuator was manufactured in the same manner as in Example 1 except that the target A shown in FIG. 9 was used as the Zr target and the annealing temperature was 900° C. Note that the target A is a target having a smaller amount of additive element than the target B. For example, the target A has a lower content of C, Al, Cr, and Fe than the target B.

### 2-1-7. Comparative Example

A piezoelectric actuator was manufactured in the same manner as in Example 6 except that the formation of the film made of titanium was omitted, that is, the formation of the third layer was omitted.

### 2-2. Intensity Ratio

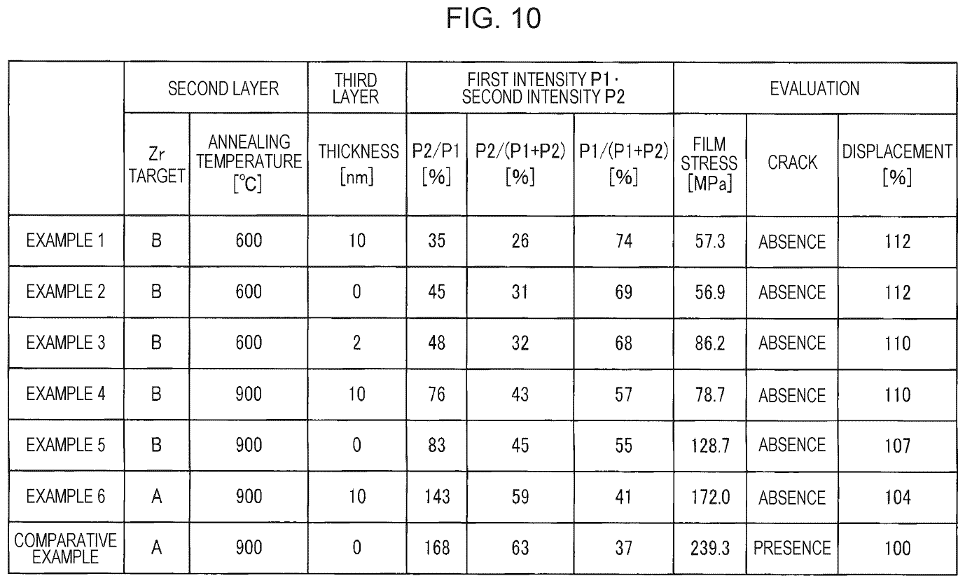

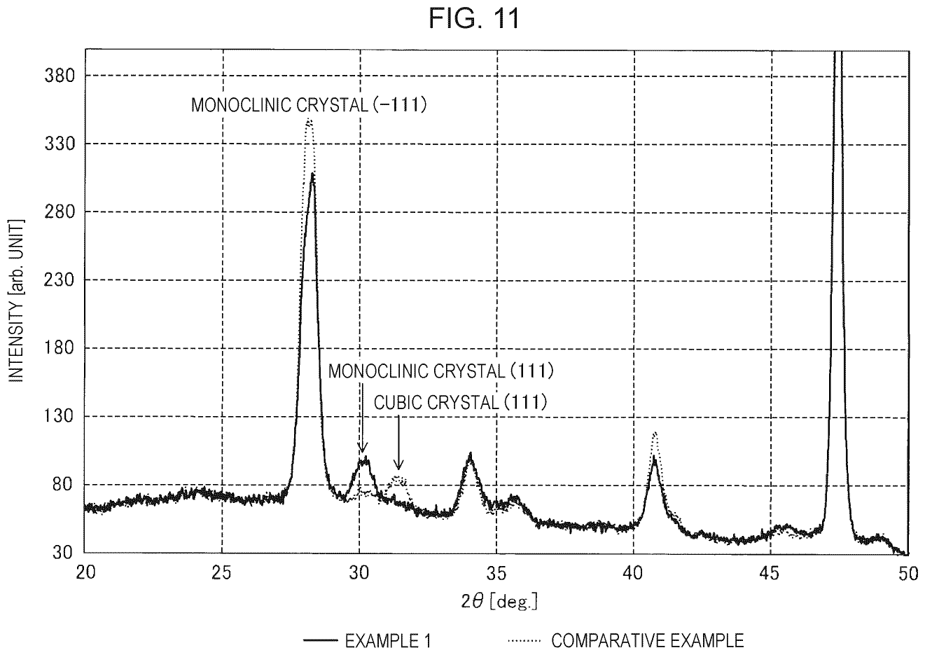

FIG. 10 shows the results of measuring the ratio P1/(P1+P2) based on the results of analyzing the second layer by X-ray analysis for Examples 1 to 6 and Comparative Example. FIG. 11 shows the results of analyzing the second layer by X-ray analysis for Example 1 and Comparative Example. Note that FIG. 10 also shows the ratio P2/P1 and the ratio P2/(P1+P2) in addition to the ratio P1/(P1+P2).

The X-ray analysis was performed by thin film X-ray diffraction using a multi-axis X-ray diffractometer. Here, using Cu as an X-ray source, and using CuKα-ray with a wavelength of 1.5418 Å as a characteristic X-ray, out-of-plane measurement, which detected a diffracted X-ray with a two-dimensional detector, was performed. Measurement was performed with a detection angle 2θ of the diffracted X-ray being 20 degrees to 50 degrees, and γ (the tilt angle on the two-dimensional detector side) being in a range of −50° to −130° when the direction perpendicular to the substrate (the position in a direction perpendicular to the substrate) was −90° and in a range of −40° to +40° when the direction perpendicular to the substrate (the position in a direction perpendicular to the substrate) was 0°.

As shown in FIG. 10, the ratio P1/(P1+P2) is 40% or more in Examples 1 to 6, whereas the ratio P1/(P1+P2) is less than 40% in Comparative Example. In addition, as shown in FIG. 11, in Example 1, the peak of the cubic crystal (111) is larger than that of Comparative Example, whereas the peak of the monoclinic crystal (111) is smaller than that of Comparative Example. In addition, in Example 1, the peak of the monoclinic crystal (−111) is smaller than that of Comparative Example.

### 2-2. Evaluation

### 2-2-1. Crack

FIG. 10 shows the results of the presence or absence of the occurrence of a crack by a durability test for Examples 1 to 6 and Comparative Example. In this durability test, when the piezoelectric element is continuously driven by applying a high voltage thereto under a high-temperature and high-humidity environment, it is measured whether a crack occurs for a specific time or less. In this test, a case where a crack occurred was determined to be “present,” and a case where a crack did not occur was determined to be “absent.”

As shown in FIG. 10, no crack occurred in Example 1 to 6, whereas a crack occurred in Comparative Example.

### 2-2-2. Displacement

FIG. 10 shows the results of measurement of the displacement amount of the vibrating plate in Examples 1 to 6 and Comparative Example. This measurement was performed by measuring the displacement amount of the vibrating plate when a voltage difference of 25 V or more was applied to the piezoelectric element. Note that the displacement amount shown in FIG. 10 is a relative value of the displacement amount in each of Examples and Comparative Example with the displacement amount in Comparative Example as a reference (100%).

As shown in FIG. 10, the displacement amount of the vibrating plate is larger in Examples 1 to 6 than in Comparative Example.

### 3. MODIFICATION EXAMPLES

The embodiments exemplified above can be modified in various ways. Specific modification aspects that can be applied to the above-described embodiments will be exemplified below. Aspects randomly selected from the following examples can be combined as appropriate to the extent that these aspects do not contradict each other.

### 3-1. Modification Example 1

In the above-described embodiment, an aspect in which the second electrode 562 is a common electrode is exemplified, but this aspect is not limiting, and the second electrode 562 may be an individual electrode for each piezoelectric element 560. In this case, the first electrode 561 may be a common electrode common to the piezoelectric elements 560. However, even when the first electrode 561 is used as a common electrode and the second electrode 562 is used as an individual electrode, the piezoelectric layer 563 includes a region that does not overlap the first electrode 561.

### 3-2. Modification Example 2

In the above-described embodiments, the serial type liquid ejecting apparatus 100 in which the transport body 41 on which the liquid ejection heads 50 are mounted is reciprocated has been exemplified, but the present disclosure is also applied to a line type liquid ejecting apparatus in which a plurality of nozzles N are distributed over the entire width of the recording medium M.

### 3-3. Modification Example 3

The liquid ejecting apparatus 100 exemplified in the above-described embodiment may be used in not only an apparatus dedicated for printing but also various apparatuses such as a facsimile machine and a copy machine, and the application of the present disclosure is not particularly limited. Note that the application of the liquid ejecting apparatus is not limited to printing. For example, a liquid ejecting apparatus that ejects a solution of a coloring material is used as a manufacturing apparatus that forms color filters of display devices such as liquid crystal display panels. In addition, a liquid ejecting apparatus that ejects a solution of a conductive material is used as a manufacturing apparatus that forms wiring or electrodes on wiring substrates. In addition, a liquid ejecting apparatus that ejects a solution of an organic substance related to a living body is used, for example, as a manufacturing apparatus that manufactures biochips.

### 4. APPENDIX

Hereinafter, appendixes to the present disclosure will be added.

(Appendix 1) A first aspect as a preferred example of a piezoelectric actuator of the present disclosure includes a piezoelectric element, and a vibrating plate that vibrates through driving of the piezoelectric element, wherein the vibrating plate includes a first layer containing zirconium oxide as a main constituent material, and when zirconium oxide contained in the first layer is measured by X-ray diffraction, and when an intensity related to a cubic crystal (111) is defined as a first intensity and an intensity related to a monoclinic crystal (111) is defined as a second intensity, a ratio of the first intensity to a sum of the first intensity and the second intensity is 40% or more.

In the above aspect, the ratio of the cubic crystal (111) can be increased with respect to the monoclinic crystal (111) in zirconium oxide contained in the first layer. As a result, the occurrence of cracks can be reduced.

(Appendix 2) In a second aspect as a preferred example of the first aspect, the ratio of the first intensity to a sum of the first intensity and the second intensity is 50% or more. In the above aspect, the displacement of the vibrating plate can be increased compared to an aspect in which the ratio is less than 50%. Therefore, the displacement of the vibrating plate can be ensured while reducing the occurrence of cracks.

(Appendix 3) In a third aspect as a preferred example of the second aspect, the ratio of the first intensity to a sum of the first intensity and the second intensity is 57% or more. In the above aspect, the film stress of the first layer can be made 100 MPa or less. As a result, the occurrence of cracks in the vibrating plate can be suitably reduced.

(Appendix 4) In a fourth aspect as a preferred example of the third aspect, the first layer has a tensile stress of 100 MPa or less. In the above aspect, the occurrence of cracks in the vibrating plate can be reduced. On the other hand, when the tensile stress of the second layer is excessively large, there is a concern that cracks may occur in the vibrating plate.

(Appendix 5) In a fifth aspect as a preferred example of any of the first aspect to the fourth aspect, the first layer contains at least one element out of carbon, aluminum, titanium, chromium, iron, hafnium, yttrium, and cerium. In the above aspect, the first intensity can be suitably made larger than the second intensity. That is, the ratio of the cubic crystal (111) can be increased.

(Appendix 6) In a sixth aspect as a preferred example of any of the first aspect to the fifth aspect, the first layer has an element having the same valence as zirconium. In the above aspect, the insulation properties of the first layer can be improved, and a leakage current to the vibrating plate can be reduced.

(Appendix 7) In a seventh aspect as a preferred example of the fifth aspect, the first layer contains carbon. In the above aspect, the film stress of the first layer can be reduced while increasing the ratio of cubic crystal (111).

(Appendix 8) In an eighth aspect as a preferred example of any of the first aspect to the seventh aspect, the vibrating plate further includes, below the first layer in a thickness direction of the first layer, a third layer containing silicon oxide, and a second layer provided between the first layer and the third layer in the thickness direction and containing an element different from zirconium, wherein the element different from zirconium is contained in the first layer. In the above aspect, by supplying an additive from the second layer to the first layer, the first intensity can be suitably made larger than the second intensity. As a result, the ratio of the cubic crystal (111) can be increased.

(Appendix 9) In a ninth aspect as a preferred example of the eighth aspect, the second layer contains titanium, and a thickness of the second layer is 10 nm or less. In the above aspect, since the second layer contains titanium, which easily thermally diffuses, titanium can be suitably diffused into the first layer. In addition, since the thickness of the second layer is 10 nm or less, a decrease in the strength of the vibrating plate can be reduced.

(Appendix 10) In a 10th aspect as a preferred example of any of the first aspect to the ninth aspect, the vibrating plate includes a second layer containing an element different from zirconium above the first layer in a thickness direction of the first layer, and the element different from zirconium is contained in the first layer. In the above aspect, by supplying an impurity from the second layer to the first layer, the first intensity can be suitably made larger than the second intensity. As a result, the ratio of the cubic crystal (111) can be increased.

(Appendix 11) In an 11th aspect as a preferred example of any of the first aspect to the 10th aspect, the vibrating plate includes a layer containing silicon oxide below the first layer in a thickness direction of the first layer. The layer containing silicon oxide has a compressive stress. On the other hand, the first layer has a tensile stress. Therefore, since the directions of the internal stresses in the layer containing silicon oxide and the first layer are opposite to each other, the internal stresses generated in the vibrating plate cancel each other out, and the internal stress of the entire vibrating plate can be reduced.

(Appendix 12) A 12th aspect as a preferred example of a liquid ejection head of the present disclosure includes the piezoelectric actuator of any of the first aspect to the 11th aspect. In the above aspect, a liquid ejection head having excellent reliability can be provided.

What is claimed is:

1. A piezoelectric actuator comprising:
a piezoelectric element; and
a vibrating plate that vibrates through driving of the piezoelectric element, wherein
the vibrating plate includes a first layer containing zirconium oxide as a main constituent material, and
when zirconium oxide contained in the first layer is measured by X-ray diffraction, and when an intensity related to a cubic crystal (111) is defined as a first intensity and an intensity related to a monoclinic crystal (111) is defined as a second intensity, a ratio of the first intensity to a sum of the first intensity and the second intensity is 40% or more.

2. The piezoelectric actuator according to claim 1, wherein the ratio of the first intensity to the sum of the first intensity and the second intensity is 50% or more.

3. The piezoelectric actuator according to claim 2, wherein the ratio of the first intensity to the sum of the first intensity and the second intensity is 57% or more.

4. The piezoelectric actuator according to claim 3, wherein the first layer has a tensile stress of 100 MPa or less.

5. The piezoelectric actuator according to claim 1, wherein the first layer contains at least one element out of carbon, aluminum, titanium, chromium, iron, hafnium, yttrium, and cerium.

6. The piezoelectric actuator according to claim 1, wherein the first layer has an element having the same valence as zirconium.

7. The piezoelectric actuator according to claim 5, wherein the first layer contains carbon.

8. The piezoelectric actuator according to claim 1, wherein the vibrating plate further includes, below the first layer in a thickness direction of the first layer:
a third layer containing silicon oxide; and
a second layer provided between the first layer and the third layer in the thickness direction and containing an element different from zirconium, wherein the element different from zirconium is contained in the first layer.

9. The piezoelectric actuator according to claim 8, wherein the second layer contains titanium, and
a thickness of the second layer is 10 nm or less.

10. The piezoelectric actuator according to claim 1, wherein
the vibrating plate includes a second layer containing an element different from zirconium above the first layer in a thickness direction of the first layer, and
the element different from zirconium is contained in the first layer.

11. The piezoelectric actuator according to claim 1, wherein the vibrating plate includes a layer containing silicon oxide below the first layer in a thickness direction of the first layer.

12. A liquid ejection head comprising the piezoelectric actuator according to claim 1.

13. A piezoelectric actuator comprising:
a piezoelectric element; and
a vibrating plate that vibrates through driving of the piezoelectric element, wherein
the vibrating plate includes a first layer containing zirconium oxide as a main constituent material, and
when zirconium oxide contained in the first layer is measured by X-ray diffraction, and when an intensity of a peak observed in a range of 2θ=29.5-30.9° is defined as a first intensity and an intensity of a peak observed in a range of 2θ=30.8-32.0° is defined as a second intensity, a ratio of the first intensity to a sum of the first intensity and the second intensity is 40% or more.
